(19) United States
(12) Patent Application Publication
(10) Pub. No.: US 2018/0053473 A1
(43) Pub. Date: Feb. 22, 2018

(54) PERIPHERAL DESIGN CIRCUIT OF LIQUID CRYSTAL DISPLAY PANEL AND LIQUID CRYSTAL DISPLAY PANEL

(71) Applicant: SHENZHEN CHINA STAR OPTOELECTRONICS TECHNOLOGY CO., LTD., GUANGDONG (CN)

(72) Inventors: Cong WANG, Guangdong (CN); Peng DU, GUANGDONG (CN)

(21) Appl. No.: 15/318,991

(22) PCT Filed: Aug. 19, 2016
(86) PCT No.: PCT/CN2016/096055

§ 371 Date: Dec. 15, 2016

(30) Foreign Application Priority Data
Jul. 13, 2016 (CN) 201610550441.8

(51) Int. Cl. G09G 3/34; G09G 3/36; H01L 27/12; H01L 23/00; G02F 1/1333; G09G 3/00

(52) U.S. Cl. CPC G09G 3/3406; G09G 3/3648; H01L 27/1214; G02F 2001/136268; G02F 1/1333; G09G 3/006; G09G 2300/0439; H01L 24/02

(57) ABSTRACT

A peripheral design circuit of a liquid crystal display (LCD) panel includes a demultiplexer, a switch test, a driver integrated circuit (driver IC) zone, and a fanout structure. The driver IC zone comprises an upper bonding pad, a lower bonding pad, and a driver IC. The upper bonding pad and the lower bonding pad are arranged opposite. The driver IC is connected to the upper bonding pad and the lower bonding pad. The fanout structure is connected to the lower bonding pad and the demultiplexer. The switch test is arranged between the upper bonding pad and the lower bonding pad. The driver IC covers the switch test. The switch test is connected to the lower bonding pad.

### BACKGROUND

### 1. Field of the Disclosure

The present invention relates to the field of liquid crystal display (LCD) panel, and more particularly, to a peripheral design circuit of an LCD panel and an LCD panel adopting the circuit.

### 2. Description of the Related Art

The size of a thin film transistor (TFT) having a low temperature poly-silicon (LTPS) is smaller with a higher aperture ratio of a pixel because the LTPS has a high electron mobility. While the display brightness of the panel is enhanced, the power consumption of the panel is reduced. So the production cost of the panel is greatly reduced. That's way the LTPS has been a popular topic for researchers and manufactures of liquid crystal display in recent years.

With constant development of a liquid crystal display (LCD) panel, a tendency for an LCD with a narrow bezel or bezel-free LCD is developing in the modern society. How to use a peripheral bezel of the LCD effectively has been a popular topic for designers of panels in recent years.

FIG. 1 is a circuit diagram of a peripheral structure of a traditional LTPS. One terminal of a fanout structure 10 is connected to a lower bonding pad 12 under a driver integrated circuit (IC) 11, and the other terminal is connected to a demultiplexer 13. The other terminal of the fanout structure 10 connected to the demultiplexer 13 is also connected to a switch test 14. The fanout structure 10 and the switch test 14 are connected in parallel in this structure. When the testing is conducted, a transmittance signal is supplied through transmittance lines ODD/EVEN of the switch test 14 in the panel, a TFT is turned on, and images are shown on the panel through the demultiplexer 13.

After the module is bonded completely, the TFT of the switch test 14 is turned off. Also, the signal is input by the driver IC 11 normally, and images are shown on the panel through the demultiplexer 13. The switch test 21 occupies a large amount of space. So it is disadvantageous to design the LCD panel with a narrow bezel.

### SUMMARY

An object of the present invention is to propose a peripheral design circuit of a liquid crystal display (LCD) panel and an LCD panel adopting the circuit to effectively save the space around the periphery of the LCD panel and to make a product designed with a narrow bezel come true.

According to the present disclosure, a peripheral design circuit of a liquid crystal display (LCD) panel includes a demultiplexer, a switch test, a driver integrated circuit (driver IC) zone, and a fanout structure. The driver IC zone comprises an upper bonding pad, a lower bonding pad, and a driver IC. The upper bonding pad and the lower bonding pad are arranged opposite. The driver IC is connected to the upper bonding pad and the lower bonding pad. The fanout structure is connected to the lower bonding pad and the demultiplexer. The switch test is arranged between the upper bonding pad and the lower bonding pad. The driver IC covers the switch test. The switch test is connected to the lower bonding pad.

In one aspect of the present disclosure, the switch test comprises an odd signal transmittance line and an even transmittance line, and the switch test is configured to output alternating current signals with opposite polarities through the odd signal transmittance line and the even transmittance line.

In another aspect of the present disclosure, the odd signal transmittance line and the even transmittance line output periodical pulse signals in a condition of synchronous phase inversion.

In another aspect of the present disclosure, the switch test comprises a signal unit switch test, and the signal unit switch test is configured to output an alternating current signal with opposite polarities.

In another aspect of the present disclosure, the switch test comprises a testing control switch, and the testing control switch is configured to control the switch test to turn on and off.

In another aspect of the present disclosure, the testing control switch is an N-type metal-oxide-semiconductor transistor (NMOS transistor), the switch test supplies a signal at high voltage level, and the NMOS transistor is turned on to turn on the switch test.

In another aspect of the present disclosure, the testing control switch is a P-type metal-oxide-semiconductor transistor (PMOS transistor), the switch test supplies a signal at low voltage level, and the PMOS transistor is turned on to turn on the switch test.

In another aspect of the present disclosure, the demultiplexer comprises an R signal control switch, a G signal control switch, and a B signal control switch.

In another aspect of the present disclosure, the R signal control switch, the G signal control switch, and the B signal control switch are NMOS transistors or PMOS transistors.

The present disclosure also proposes a liquid crystal display panel having a display zone and a non-display zone. The peripheral design circuit as provided above is disposed on the non-display zone.

The merit of the present invention is that the space around the periphery of the LCD panel is effectively saved without affecting the display effect of the LCD panel to make the LCD panel designed with a narrow bezel come true and to enhance the outlook effect of the LCD panel.

### BRIEF DESCRIPTION OF THE DRAWINGS

FIG. 1 is a circuit diagram of a peripheral structure of a traditional LTPS.

FIG. 2 is a schematic diagram of a peripheral design circuit of the LCD panel according to a first embodiment of the present invention.

FIG. 3 is a timing diagram of each signal in the peripheral design circuit of the LCD panel according to the first embodiment of the present invention.

FIG. 4 is a schematic diagram of a peripheral design circuit of a liquid crystal display panel according to a second embodiment of the present invention.

FIG. 5 is a timing diagram of each signal in the peripheral design circuit of a liquid crystal display panel according to the second embodiment of the present invention.

FIG. 6 is a schematic diagram of a peripheral design circuit of a liquid crystal display panel according to a third embodiment of the present invention.

FIG. 7 is a timing diagram of each signal in the peripheral design circuit of the LCD panel according to the third embodiment of the present invention.

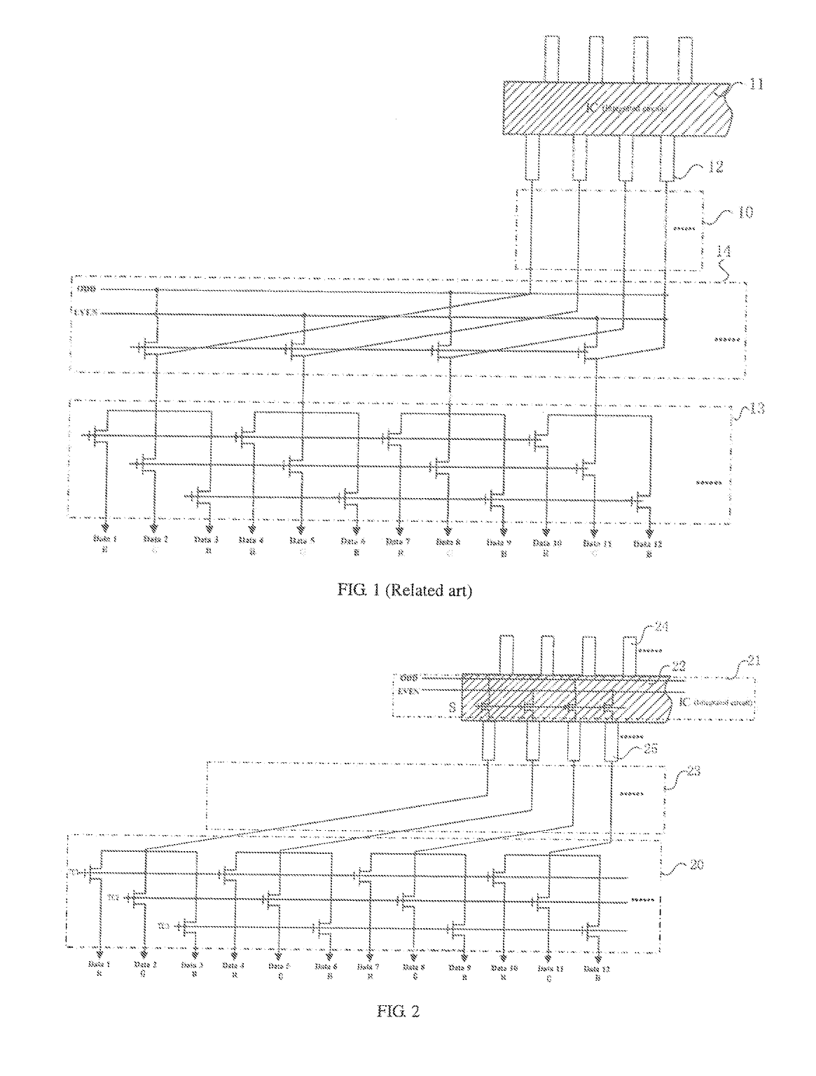

### DETAILED DESCRIPTION OF THE PREFERRED EMBODIMENTS

A peripheral design circuit of a liquid crystal display (LCD) panel and an LCD panel adopting the circuit are proposed by the present invention. The peripheral design circuit of the LCD panel and the LCD panel adopting the circuit are detailed with reference to the relative figures.

FIG. 2 is a schematic diagram of a peripheral design circuit of the LCD panel according to a first embodiment of the present invention. The peripheral design circuit comprises a demultiplexer 20, a switch test 21, a driver integrated circuit (driver IC) zone 22, and a fanout structure 23.

The driver IC zone 22 comprises an upper bonding pad 24, a lower bonding pad 25, and a driver IC 22. The upper bonding pad 24 and the lower bonding pad 25 are arranged opposite. The driver IC 22 is connected to the upper bonding pad 24 and the lower bonding pad 25. The fanout structure 23 is connected to the lower bonding pad 25 and the demultiplexer 20.

The switch test 21 is arranged between the upper bonding pad 24 and the lower bonding pad 25. The driver IC 22 covers the switch test 21. The switch test 21 is connected to the lower bonding pad 25. The switch test 21 is connected to the fanout structure 23 in series through the lower bonding pad 25.

The switch test 21 comprises an odd signal transmittance line ODD and an even transmittance line EVEN. The odd signal transmittance line ODD and the even transmittance line EVEN are used to output alternating current (AC) signals with opposite polarities. Both of the odd signal transmittance line ODD and the even transmittance line EVEN output periodical pulse signals while the output periodical pulse signals are in a condition of synchronous phase inversion. The switch test 21 further comprises a testing control switch S. The testing control switch S is used to control the switch test 21 to turn on and off. The testing control switch S is an N-type MOS transistor (NMOS transistor) in this embodiment.

The demultiplexer 20 comprises an R signal control switch TC1, a G signal control switch TC2, and a B signal control switch TC3. The R signal control switch TC1, the G signal control switch TC2, and the B signal control switch TC3 are used to control a data signal to feed a red/green/blue (ROB) pixel unit. The R signal control switch TC1, the C signal control switch TC2, and the B signal control switch TC3 are all NMOS transistors in this embodiment.

The working procedure of the peripheral design circuit of the LCD panel is described as follows:

In the testing process, the testing control switch S is turned on. The signal is transmitted through the transmittance lines ODD/EVEN. The signal is transmitted to the fanout structure 23 and then to the demultiplexer 20 to drive the panel to show images. After the testing closes, the testing control switch S is turned off, and the driver IC 22 is transmitted to the fanout structure 23 and then to the demultiplexer 20 to drive the panel to show images normally.

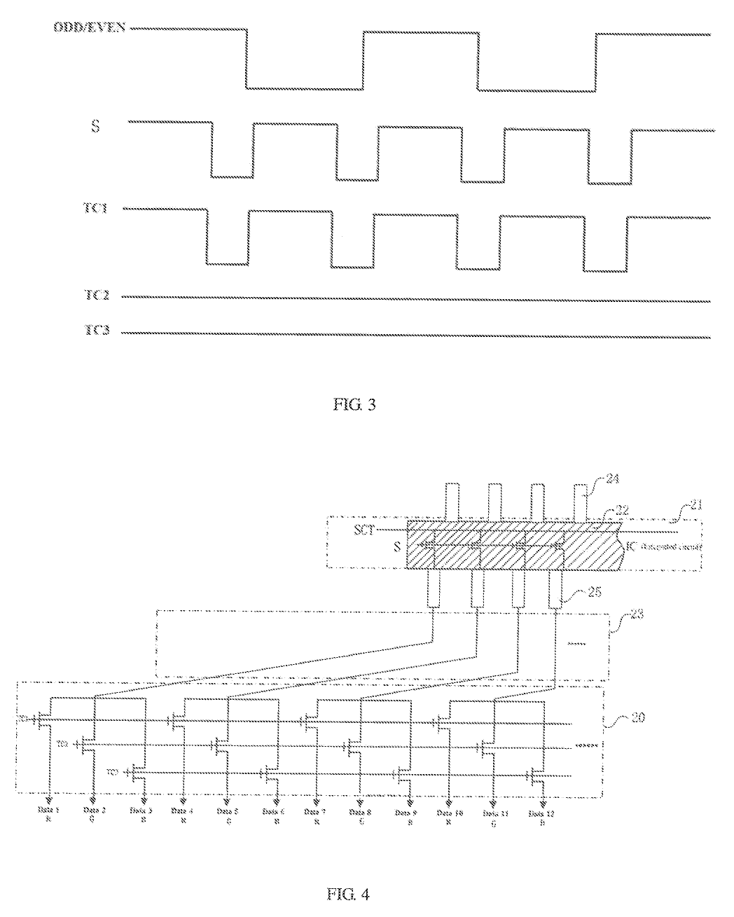

FIG. 3 is a timing diagram of each signal in the peripheral design circuit of the LCD panel according to the first embodiment of the present invention. The timing diagram is a timing diagram of each signal when a red image is shown on the LCD panel. The transmittance lines ODD/EVEN supply an alternating current signal with polarity inversion. When the alternating current signal is at high voltage level, the testing control switch S is turned on. When the R signal control switch TC1 is at high voltage level, the R signal control switch TC1 is turned on. Also, a signal is input to the R pixel; the G signal control switch TC2 and the B signal control switch TC3 keep low voltage level when being output; no signals are input to the G pixel and the B pixel; the image shown on the LCD panel is red. Likewise, when the R signal control switch TC1 and the B signal control switch TC3 keep low voltage level and the G signal control switch TC2 is at high voltage level, the signal is input to the G pixel and the image shown on the LCD panel is green. When the R signal control switch TC1 and the G signal control switch TC2 are low voltage level and the B signal control switch TC3 is at high voltage level, the signal is input to the B pixel and the image shown on the LCD panel is blue.

Since the switch test 21 is arranged between the upper bonding pad 24 and the lower bonding pad 25 in this embodiment, no space is occupied by the switch test 21. So it is beneficial to design the LCD panel with a narrow bezel adopting the embodiment.

FIG. 4 is a schematic diagram of a peripheral design circuit of a liquid crystal display panel according to a second embodiment of the present invention. Different from the first embodiment, a signal unit switch test SCT for supplying a testing signal is used by the switch test 21 in this embodiment. The signal unit switch test SCT is used to output an alternating current signal with opposite polarities.

FIG. 5 is a timing diagram of each signal in the peripheral design circuit of a liquid crystal display panel according to the second embodiment of the present invention. The timing diagram is a timing diagram of each signal when a red image is shown on the LCD panel. The signal unit switch test SCT supplies the alternating current signal with polarity inversion. When the alternating current signal is at high voltage level, the testing control switch S is turned on. When the R signal control switch TC1 at high voltage level, the R signal control switch TC1 is turned on. Also, a signal is input to the R pixel; the G signal control switch TC2 and the B signal control switch TC3 keep low voltage level when being output; no signals are input to the G pixel and the B pixel; the image shown on the LCD panel is red.

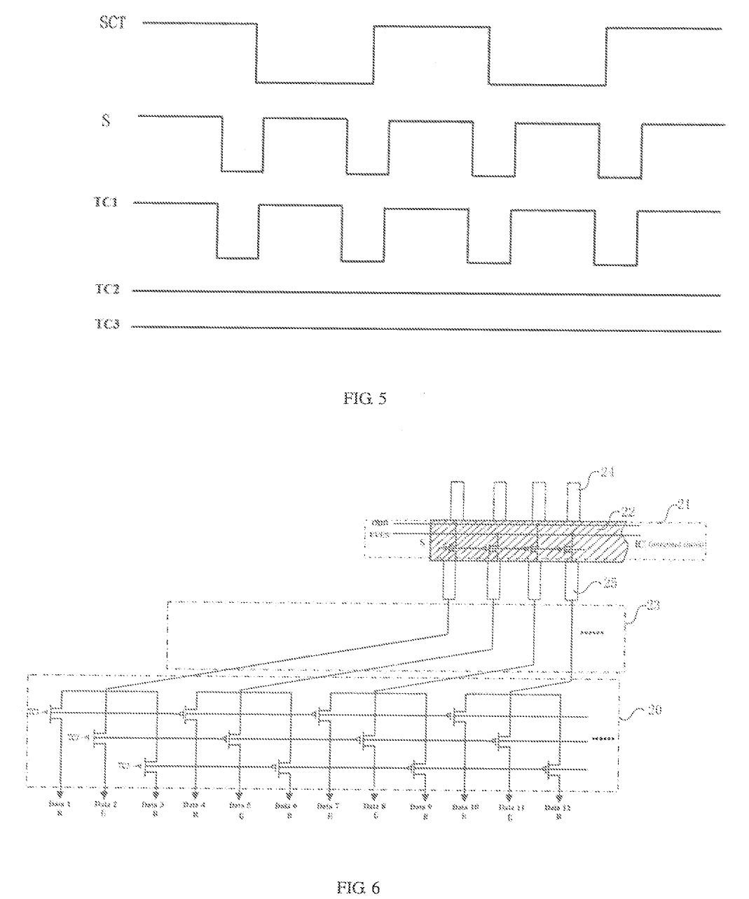

FIG. 6 is a schematic diagram of a peripheral design circuit of a liquid crystal display panel according to a third embodiment of the present invention. In contrast to the first embodiment, in the third embodiment a testing control switch S, a R signal control switch TC1, a G signal control switch TC2, and a B signal control switch TC3 are all the PMOS transistors. Besides, an alternating current signal with opposite polarities output by an odd signal transmittance line ODD and by an even transmittance line EVEN is adopted by a switch test 21. Or, an alternating current signal with opposite polarities output by a signal unit switch test SCT is adopted by the switch test 21.

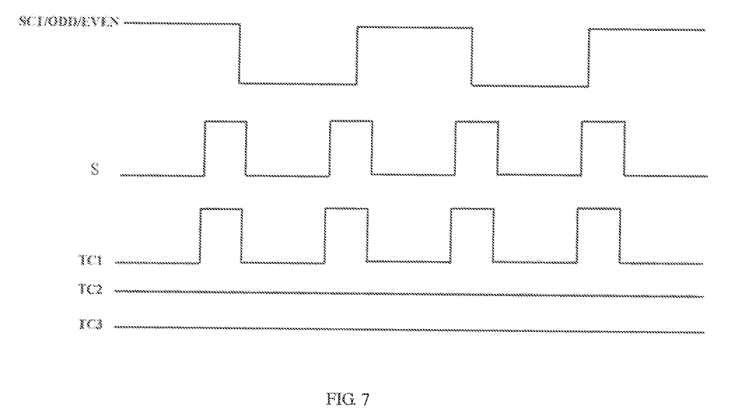

FIG. 7 is a timing diagram of each signal in the peripheral design circuit of the LCD panel according to the third embodiment of the present invention. The timing diagram is a timing diagram of each signal when a red image is shown on the LCD panel. A signal unit switch test SCT or an odd signal transmittance line ODD and an even transmittance line EVEN supply the alternating current signal with polarity inversion. When the alternating current signal is at low voltage level, the testing control switch S is turned on. When the R signal control switch TC1 is at low voltage level, the R signal control switch TC1 is turned on. Also, a signal is input to the R pixel; the G signal control switch TC2 and the B signal control switch TC3 keep high voltage level when being output; no signals are input to the G pixel and the B pixel; an image shown on the LCD panel is red. Likewise, when the R signal control switch TC1 and the B signal control switch TC3 keep high voltage level and the G signal control switch TC2 is at low voltage level, the signal is input to the G pixel and the image shown on the LCD panel is green. When the R signal control switch TC1 and the G signal control switch TC2 are high voltage level and the B signal control switch TC3 is at low voltage level, the signal is input to the B pixel and the image shown on the LCD panel is blue. An LCD panel (not shown) is further proposed by the present invention. The LCD panel comprises a display zone and a non-display zone. The non-display zone comprises the above-mentioned peripheral design circuit of the LCD panel. A switch test is arranged between an upper bonding pad and a lower bonding pad in the LCD panel so the space occupied by the switch test is effectively saved, which is beneficiary to design the LCD panel with a narrow bezel.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

What is claimed is:

1. A peripheral design circuit of a liquid crystal display (LCD) panel, comprising a demultiplexer, a switch test, a driver integrated circuit (driver IC) zone, and a fanout structure, wherein the driver IC zone comprises an upper bonding pad, a lower bonding pad, and a driver IC; the upper bonding pad and the lower bonding pad are arranged opposite; the driver IC is connected to the upper bonding pad and the lower bonding pad; the fanout structure is connected to the lower bonding pad and the demultiplexer, wherein the switch test is arranged between the upper bonding pad and the lower bonding pad; the driver IC covers the switch test; the switch test is connected to the lower bonding pad,
wherein the switch test comprises an odd signal transmittance line and an even transmittance line, and the switch test is configured to output alternating current signals with opposite polarities through the odd signal transmittance line and the even transmittance line,
wherein the switch test comprises a testing control switch, and the testing control switch is configured to control the switch test to turn on and off.

2. The peripheral design circuit of claim 1, wherein the odd signal transmittance line and the even transmittance line output periodical pulse signals in a condition of synchronous phase inversion.

3. The peripheral design circuit of claim 1, wherein the testing control switch is an N-type metal-oxide-semiconductor transistor (NMOS transistor), the switch test supplies a signal at high voltage level, and the NMOS transistor is turned on to turn on the switch test.

4. The peripheral design circuit of claim 1, wherein the testing control switch is a P-type metal-oxide-semiconductor transistor (PMOS transistor), the switch test supplies a signal at low voltage level, and the PMOS transistor is turned on to turn on the switch test.

5. A peripheral design circuit of a liquid crystal display (LCD) panel, comprising a demultiplexer, a switch test, a driver integrated circuit (driver IC) zone, and a fanout structure, wherein the driver IC zone comprises an upper bonding pad, a lower bonding pad, and a driver IC; the upper bonding pad and the lower bonding pad are arranged opposite; the driver IC is connected to the upper bonding pad and the lower bonding pad; the fanout structure is connected to the lower bonding pad and the demultiplexer, wherein the switch test is arranged between the upper bonding pad and the lower bonding pad; the driver IC covers the switch test; the switch test is connected to the lower bonding pad.

6. The peripheral design circuit of claim 5, wherein the switch test comprises an odd signal transmittance line and an even transmittance line, and the switch test is configured to output alternating current signals with opposite polarities through the odd signal transmittance line and the even transmittance line.

7. The peripheral design circuit of claim 6, wherein the odd signal transmittance line and the even transmittance line output periodical pulse signals in a condition of synchronous phase inversion.

8. The peripheral design circuit of claim 5, wherein the switch test comprises a signal unit switch test, and the signal unit switch test is configured to output an alternating current signal with opposite polarities.

9. The peripheral design circuit of claim 5, wherein the switch test comprises a testing control switch, and the testing control switch is configured to control the switch test to turn on and off.

10. The peripheral design circuit of claim 9, wherein the testing control switch is an N-type metal-oxide-semiconductor transistor (NMOS transistor), the switch test supplies a signal at high voltage level, and the NMOS transistor is turned on to turn on the switch test.

11. The peripheral design circuit of claim 9, wherein the testing control switch is a P-type metal-oxide-semiconductor transistor (PMOS transistor), the switch test supplies a signal at low voltage level, and the PMOS transistor is turned on to turn on the switch test.

12. The peripheral design circuit of claim 5, wherein the demultiplexer comprises an R signal control switch, a G signal control switch, and a B signal control switch.

13. The peripheral design circuit of claim 12, wherein the R signal control switch, the G signal control switch, and the B signal control switch are NMOS transistors or PMOS transistors.

14. A liquid crystal display panel comprising a display zone and a non-display zone, wherein a peripheral design circuit as claimed in claim 1 is disposed on the non-display zone.
